(19) United States
(12) Patent Application Publication
(10) Pub. No.: US 2010/0303435 A1
(43) Pub. Date: Dec. 2, 2010

(54) OPTICAL DEVICE AND METHOD OF FABRICATING THE SAME

(75) Inventors: Sahnggi Park, Daejeon (KR); Kap-Joong Kim, Daejeon (KR); Duk Jun Kim, Daejeon (KR); Gyungock Kim, Seoul (KR)

Correspondence Address: AMPACC Law Group, 3500 188th Street S.W., Suite 103, Lynnwood, WA, 98037, US

(73) Assignee: Electronics and Telecommunications Research Institute, Daejeon (KR)

(21) Appl. No.: 12/555,767

(22) Filed: Sep. 8, 2009

(30) Foreign Application Priority Data
May 26, 2009 (KR) 10-2009-0045797

(51) Int. Cl. G02B 6/00; G03F 7/20

(52) U.S. Cl. 385/141; 430/321

(57) ABSTRACT

Provided are an optical device and a method of fabricating the same. The optical device includes: a substrate; and a ring resonator on the substrate. The ring resonator includes: a cladding layer including a lower cladding layer and an upper cladding layer on the substrate; a core including a plurality of rings between the lower cladding layer and the upper cladding layer; and an embeded layer interposed between the core and the cladding layer and having a refractive index less than that of the core and more than that of the cladding layer.

### CROSS-REFERENCE TO RELATED APPLICATIONS

This U.S. non-provisional patent application claims priority under 35 U.S.C. §119 of Korean Patent Application No. 10-2009-0045797, filed on May 26, 2009, the entire contents of which are hereby incorporated by reference.

### BACKGROUND

The present invention disclosed herein relates to an optical device and a method of fabricating the same, and more particularly, to an optical device including a ring resonator and a method of fabricating the same.

Among the latest researches for an optical device, research for a silicon optical device using silicon is actively in progress. In a case of the silicon optical device, it can be coupled to a semiconductor device formed of silicon without difficulties. Therefore, the silicon optical device can provide excellent characteristics during a formation process or in a finished product. Especially, a ring resonator using silicon is very useful as a core device, which is applicable to various fields such as a modulator, a switch, and a filter.

However, a statistical wavelength shift due to fabricating processes and limitations due to a narrow interval between patterns need to be resolved during formation processes of the ring resonator using silicon.

### SUMMARY

The present invention provides an optical device including a ring resonator with an improved transmission characteristic, and a method of fabricating the same.

The present invention also provides an optical device including a ring resonator with uniform resonance wavelengths, and a method of fabricating the same.

Embodiments of the present invention provide optical devices including: a substrate; and a ring resonator on the substrate. The ring resonator includes: a cladding layer including a lower cladding layer and an upper cladding layer on the substrate; a core including a plurality of rings between the lower cladding layer and the upper cladding layer; and an embeded layer interposed between the core and the cladding layer and having a refractive index less than that of the core and more than that of the cladding layer.

In some embodiments, the rings are spaced from each other, and the embeded layer is provided to a space between the spaced rings.

In other embodiments, the core is formed of silicon; the cladding layer is formed of a silicon oxide; and the embeded layer is formed of a silicon nitride or a silicon oxynitride.

In still other embodiments, one interval between the rings is different from another interval between the rings.

In even other embodiments, a thickness of the embeded layer adjacent to at least one ring is different from that of the embeded layer adjacent to another ring.

In yet other embodiments, an interval between the rings is more than or equal to about 160 nm.

In further embodiments, the optical device further includes a complementary metal oxide semiconductor (CMOS) region including a channel layer, the CMOS region being spaced from the ring resonator, the channel layer being provided at the same height as the core and being formed of the same material as the core.

In other embodiments of the present invention, methods of fabricating an optical device include: providing a substrate including a resonance region; forming a core including a plurality of rings by patterning a core layer; forming an embeded layer at a space between the rings of the core; and forming a cladding layer on the embeded layer, wherein the embeded layer has a refractive index less than that of the core and more than that of the cladding layer.

In some embodiments, the patterning of the core layer comprises performing a photolithography process.

In other embodiments, the patterning of the core layer is performed to allow an interval of the rings to be more than about 160 nm.

In still other embodiments, the substrate and the core layer are formed of silicon; and the substrate includes the core layer, and a buried oxide layer interposed between the substrate and the core layer.

In even other embodiments, the substrate further includes a CMOS region spaced apart from the resonance region; and the patterning of the core layer includes forming a channel layer of a transistor in the CMOS region.

In yet other embodiments, the forming of the embeded layer at the space between the core layer and the rings includes forming the embeded layer on the rings.

In further embodiments, the methods further include adjusting a spectrum of a resonance wavelength by etching an embeded layer on at least one ring to allow a thickness of the embeded layer to be thinner than that of an embeded layer on another ring.

In still further embodiments, the core layer is formed of silicon; the cladding layer is formed of a silicon oxide; and the embeded layer is formed of a silicon nitride or a silicon oxynitride.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1A is a plan view of an optical device according to an embodiment of the present invention;

FIG. 1B is a sectional view taken along the lines A-A′ and B-B′ of FIG. 1A;

FIGS. 2 through 7 are views illustrating a method of fabricating an optical device according to an embodiment of the present invention;

FIGS. 8A and 8B are views illustrating effects according to embodiments of the present invention;

FIGS. 9A and 9C are views illustrating effects according to embodiments of the present invention; and

FIGS. 10A and 10B are views illustrating effects according to embodiments of the present invention.

### DETAILED DESCRIPTION OF EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present.

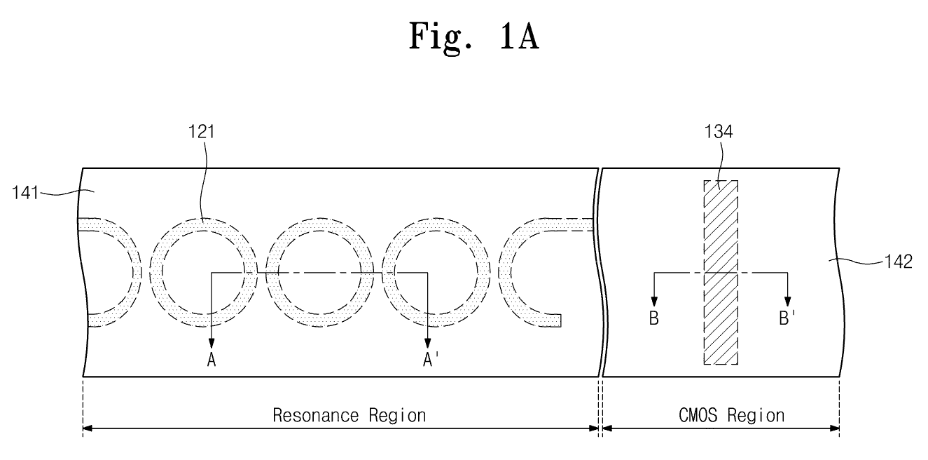

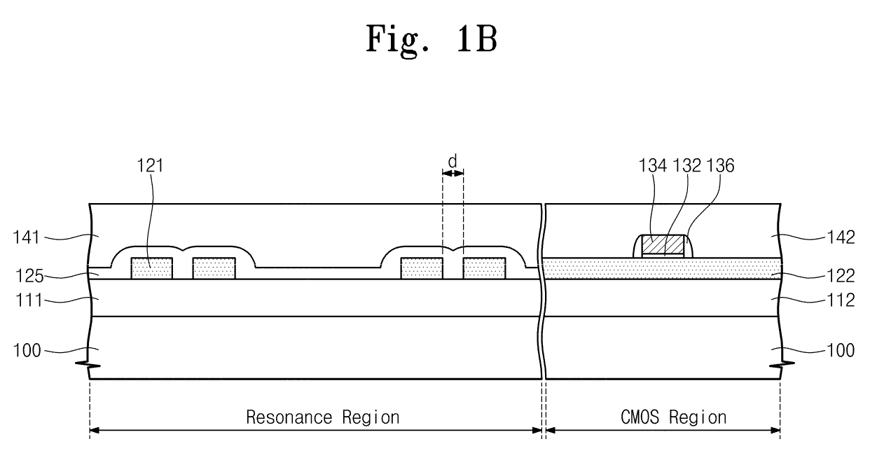

Referring to FIGS. 1A and 1B, an optical device according to an embodiment of the present invention will be described. FIG. 1A is a plan view of an optical device according to an embodiment of the present invention. FIG. 1B is a sectional view taken along the lines A-A′ and B-B′ of FIG. 1A.

A substrate 100 including a resonance region and a complementary metal oxide semiconductor (CMOS) region is provided. The substrate 100 may be a semiconductor substrate. The substrate 100 may be a silicon on insulator (SOI) substrate.

A ring resonator may be provided in the resonance region of the substrate 100. The ring resonator may include a cladding layer and a core 121. The cladding layer includes a lower cladding layer 111 and an upper cladding layer 141. The core 121 is interposed between the lower cladding layer 111 and the upper cladding layer 141. The core 121 may include a plurality of rings. The rings may be separately disposed on the lower cladding layer 111. An interval d between the rings may be more than or equal to about 160 nm. In the embodiment, intervals between the rings may vary.

An embeded layer 125 may be interposed between the core 121 and the cladding layer. The embeded layer 125 may cover the top surface of the core 121. Furthermore, the embeded layer 125 may extend to a space between the spaced rings. The embeded layer 125 may have a refractive index less than that of the core 121 and more than that of the upper and lower cladding layers 141 and 111. In the embodiment, the core 121 may be formed of silicon, the upper and lower cladding layers 141 and 111 may be formed of a silicon oxide, and the embeded layer 125 may be formed of a silicon nitride or a silicon oxynitride. If the substrate 100 is a SOI substrate, the lower cladding layer 111 may be a portion of a buried oxide layer constituting the SOI substrate. At this point, the core 121 may be a portion of a silicon layer of the SOI substrate.

An effective coupling distance between the rings that constitute the core 121 can be reduced by the embeded layer 125. When light is provided to an optical device including a core and cladding layer, it may transmit the inside of the core through total reflection at the interface between the core and the cladding layer. At this point, a portion of the transmitted light may extend to the cladding layer adjacent to the core. That is, a waveguide width of the light may be greater than the width of the core.

When the embeded layer 125 is provided between the core 121 and the cladding layer according to the embodiment of the present invention, light extends to the core 121 and the embeded layer 125 adjacent to the core 121 and then penetrates them. That is, the waveguide width of the light can be increased more. Due to the increase of the waveguide width of the light, an effective refractive index at a portion where the light penetrates is decreased, and furthermore, an effective coupling distance between adjacent rings may be reduced more than a distance of actual rings. Accordingly, the rings can be disposed at a greater interval d than when the embeded layer 125 is not embeded. In the embodiment, the interval d between the rings may be more than about 160 nm.

The CMOS region of the substrate 100 may be spaced apart from the resonance region. At least one transistor may be disposed in the CMOS region.

The transistor may include a channel layer 122 and a gate structure on the channel layer 122. The gate structure may include a gate insulation layer 132 and a gate electrode 134, which are sequentially stacked thereon. A spacer 136 may be disposed on the sidewall of the gate electrode 134. A source region and a drain region (not shown) may be disposed in the channel layer 122.

The channel layer 122 may be provided with the same height as the core 121. Additionally, the channel layer 122 may be formed of the same material as the core 121. For example, the channel layer 122 and the core 121 may be formed of single crystal silicon.

The resonance region and the CMOS region may share the buried oxide layer of the SOI substrate. The buried oxide layer of the resonance region may be the lower cladding layer 111.

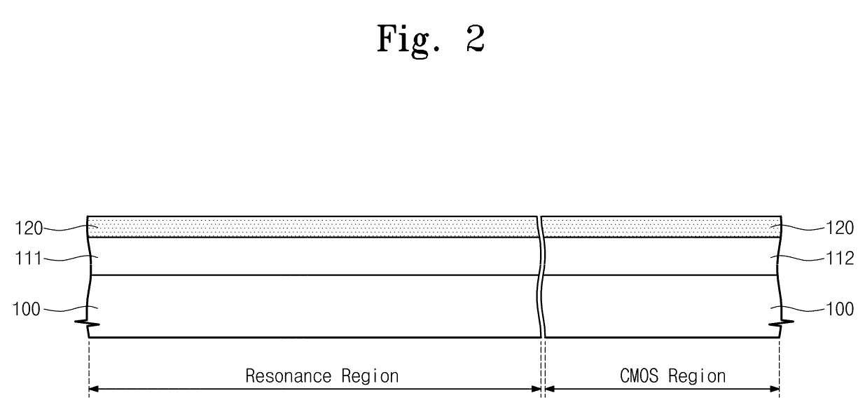

Referring to FIGS. 2 to 6, a method of fabricating an optical device according to an embodiment of the present invention will be described.

Referring to FIG. 2, a substrate structure includes a substrate 100, and buried oxide layers 111 and 112 and a core layer 120 on the substrate 100. The buried oxide layer may be a silicon oxide layer. The core layer may be a silicon layer. The substrate structure may be a SOI substrate. One region of the substrate structure constitutes a resonance region and the other region constitutes a CMOS region. The burred oxide layer of the resonance region may serve as a lower cladding layer 111.

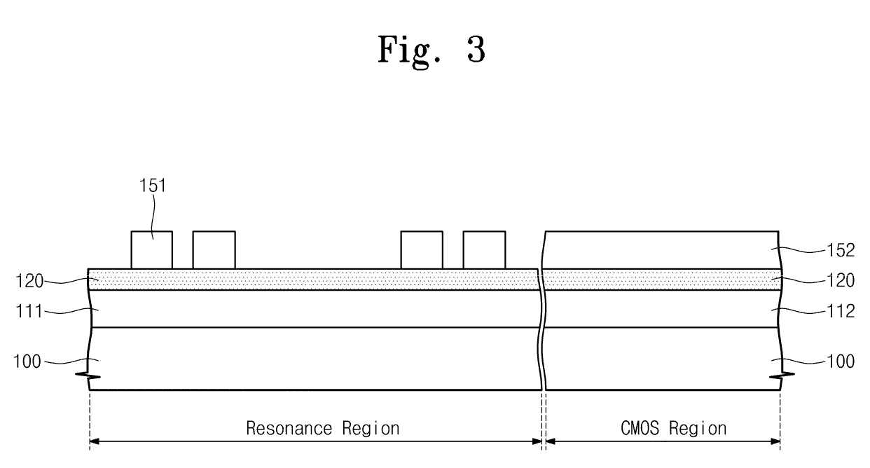

Referring to FIG. 3, mask patterns 151 and 152 may be formed on the substrate 100. The mask patterns 151 and 152 may cover all the CMOS region of the substrate 100 and partially cover the resonance region.

The forming of the mask patterns 151 and 152 may include forming a photoresist layer on the substrate 100 and performing exposure and development processes on the photoresist layer. During the exposure process, ArF or KrF light source may be used.

The mask pattern 151 in the resonance region may be a plurality of patterns. The mask pattern 151 on the resonance region may have a ring shape. The mask patterns 151 on the resonance region may be spaced a predetermined interval from each other. In the embodiment, the mask patterns 151 may be separately formed to allow an interval between patterns, which are formed through an etching process using the mask patterns 151 as a mask, to be more than or equal to about 160 nm.

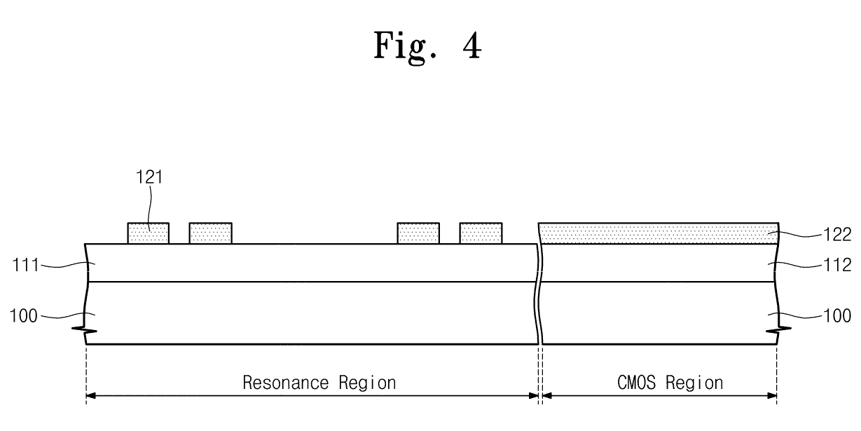

Referring to FIG. 4, an etching process using the mask patterns 151 and 152 as an etching mask is performed. By the etching process, a core 121 is formed in the resonance region. Simultaneously, a channel layer 122 may be formed in the CMOS region. The core 121 may include a plurality of rings. The rings may be disposed to be spaced apart from each other. An interval between the rings may be more than about 160 nm. In the embodiment, an interval between the rings may vary.

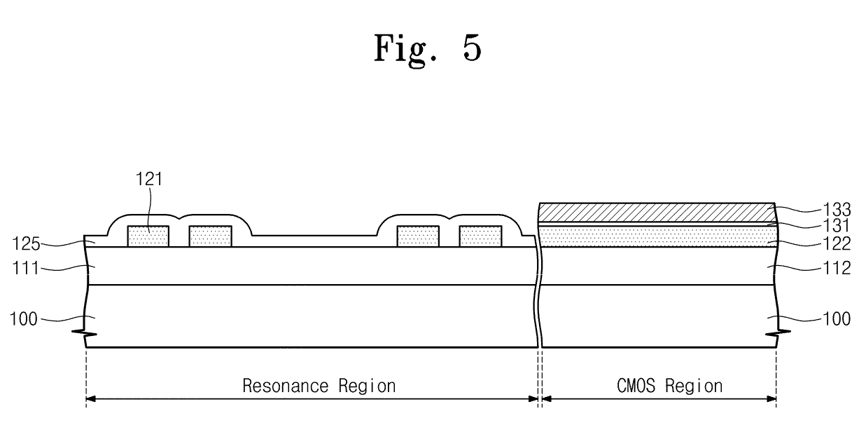

Referring to FIG. 5, an embeded layer 125 is formed to cover the resonance region of the substrate 100. The embeded layer 125 may be formed by forming a predetermined material layer on an entire surface of the substrate 100 and then removing the material layer formed in the CMOS layer. The embeded layer 125 may be formed of a material having a refractive index less than that of the core 121 and a refractive index greater than those of the lower cladding layer 111 and the upper cladding layer 141 formed later. For example, the embeded layer 125 may be formed of a silicon nitride layer or a silicon oxynitride layer.

The embeded layer 125 may be formed on the lower cladding layer 111 of the resonance region and the core 121. Furthermore, the embeded layer 125 may fill an interval between rings constituting the core 121.

Because of the embeded layer 125, characteristics of the ring resonator including the embeded layer 125 can be more improved. In more detail, in order for resonance between rings constituting the core 121, the rings need to be disposed at an interval that is less than an effective coupling distance (for example, less than about 100 nm). Accordingly, if the embeded layer 125 is not embeded between the cores 121, adjacent rings need to be disposed to have a very narrow interval. In general, an interval between the rings cannot be sufficiently narrow using a photolithography process. Therefore, the rings should be formed by an E-beam lithography process. This E-beam lithography process has an advantage that a process for maintaining a narrow interval between patterns can be accomplished but has a disadvantage that patterns formed by the E-beam lithography process may not design uniform widths and intervals between patterns. Accordingly, the rings formed by the E-beam lithography process may have respectively different resonance wavelengths. For example, a transmission spectrum form of the ring resonator formed by the E-beam lithography may be a spiky type.

However, as mentioned above, in a case of a ring resonator having an embeded layer 125, an effective coupling distance between rings constituting the core 121 can be reduced by the embeded layer 125. Accordingly, an interval between the rings may be increased more (for example, more than or equal to about 160 nm). The rings of these intervals can be realized by a photolithography process. The photolithography process generates a statistical error less than the E-beam lithography process. Accordingly, as mentioned above, the patterns formed by the photolithography process may be formed with a uniform interval and/or a uniform line width. Therefore, a ring resonator having an improved transmission spectrum characteristic may be formed.

After the forming of the embeded layer 125, a gate insulation layer 131 and a gate layer 133 may be formed in the CMOS region of the substrate 100. The gate insulation layer 131 may be formed by oxidizing the surface of the channel layer 122. The gate layer 133 may be a doped semiconductor material layer or a metal containing layer.

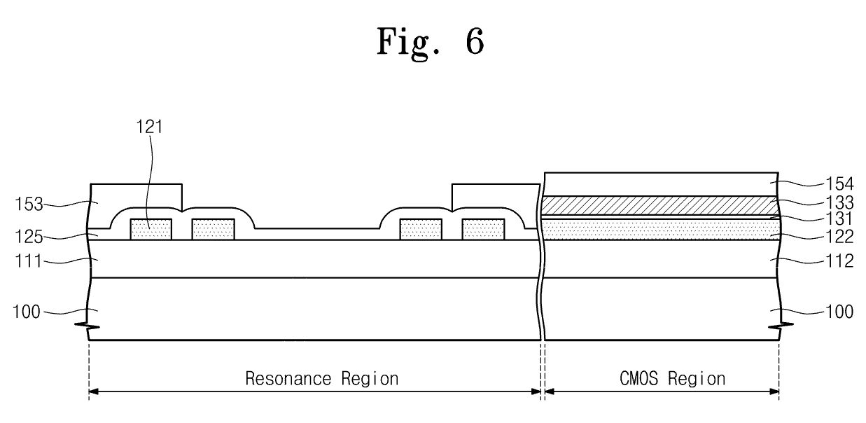

According to the embodiment, resonance wavelengths of the rings may be finely adjusted by each ring. Referring to FIG. 6, a mask pattern 153 may be formed on selected rings. The mask pattern 153 may partially cover the embeded layer 125.

Using the mask pattern 153 as an etching mask, an anisotropic etching process is performed on the exposed embeded layer 125. An etched embeded layer 125 on at least one of the rings may have the lower top surface than an unetched embeded layer 125 on the adjacent ring. That is, the thickness of the embeded layer 125 on one ring may be different from that of the embeded layer 125 on another ring.

As mentioned above, if the embeded layer 125 is included in the ring resonator, the waveguide width of the light that penetrates the rings may be increased. The waveguide width of the light may be adjusted by the thickness of the embeded layer 125. Accordingly, by adjusting the embeded layer 125 on the rings, a statistical error that may occur during the forming of the rings can be compensated. That is, if a part of the rings constituting the core 121 may be formed with the different widths than others and with the different intervals between the rings, the thickness of the embeded layer 125 on the part of the rings is adjusted to have the same resonance wavelengths as the other rings.

The thickness of the embeded layer 125 may be adjusted by performing various etching processes. For example, the embeded layer 125 can be etched by performing a reactive ion etching (RIE) process. Since the etching thickness of the embeded layer 125 can be adjusted easily by adjusting an etching time, a resonance wavelength of each ring can be easily adjusted.

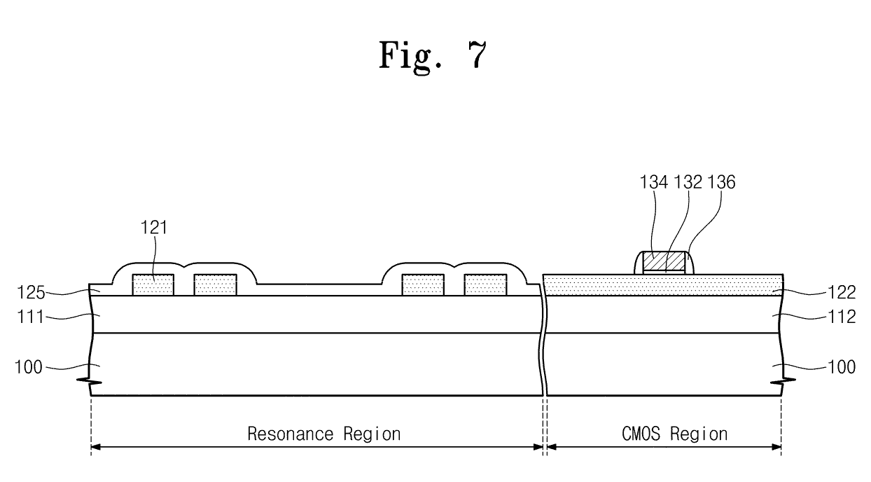

Referring to FIG. 7, the gate insulation layer 131 and the gate layer 133 of the CMOS region can be patterned. Accordingly, a transistor including a channel layer 122, a gate insulation layer 132, and a gate electrode 134 may be formed in the CMOS region. A spacer 136 may be formed on the sidewall of the gate electrode 134. Components constituting the transistor may be formed using another order and another method besides the above mentioned order and method.

Referring to FIGS. 1A and 1B again, the upper cladding layer 141 is formed on the resonance region of the substrate 100 to cover the embeded layer 125. Simultaneously, an interlayer insulation layer 142 may be formed together to cover the transistor of the CMOS region. The upper cladding layer 141 and the interlayer insulation layer 142 may be formed of the same material. For example, the upper cladding layer 141 and the interlayer insulation layer 142 may be a silicon oxide layer.

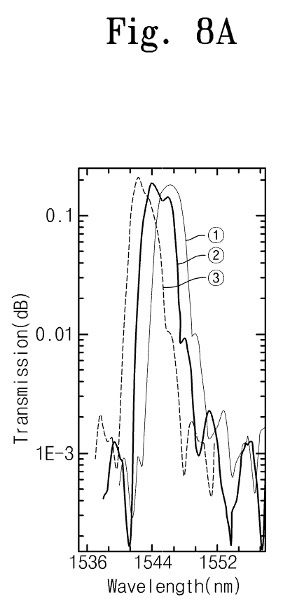

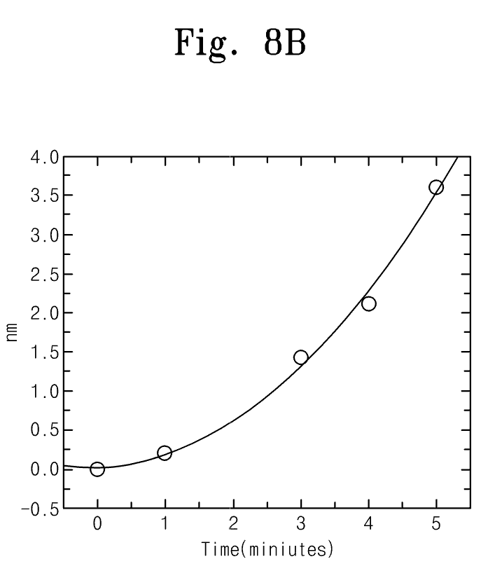

Referring to FIGS. 8A, 8B, 9A to 9C, 10A, and 10B, effects of the embodiments of the present invention will be described.

FIG. 8A is a view illustrating a transmission spectrum of a ring resonator including a core with three rings connected in series and an embeded layer. FIG. 8B is a view illustrating an etching thickness according to a time of the embeded layer of FIG. 1A. According to the embodiments, a core layer is formed of silicon, upper and lower cladding layers are formed of a silicon oxide, and an embeded layer may be formed of a silicon nitride. The embeded layer is etched by stages through the RIE process. The embeded layer is etched at an etching speed of about 500 Å/min. The curve \textcircled{1} shown in the graph represents measured values when an etching time is 0 min, that is, before the etching process. The curve \textcircled{2} represents measured values when an etching time is 3 min. The curve \textcircled{3} represents measured values when an etching time is 5 min.

As shown in FIG. 8A, when the thickness of the embeded layer is gradually decreased, a transmission spectrum is shifted without a change of a wavelength interval between each ring. That is, the resonance wavelength of the ring is uniformly shifted. The resonance wavelength of the ring is shifted to a lower wavelength region as the thickness of the embeded layer becomes thinner. Moreover, a form and a total power of a spectrum almost do not change after and before the shift of the wavelength.

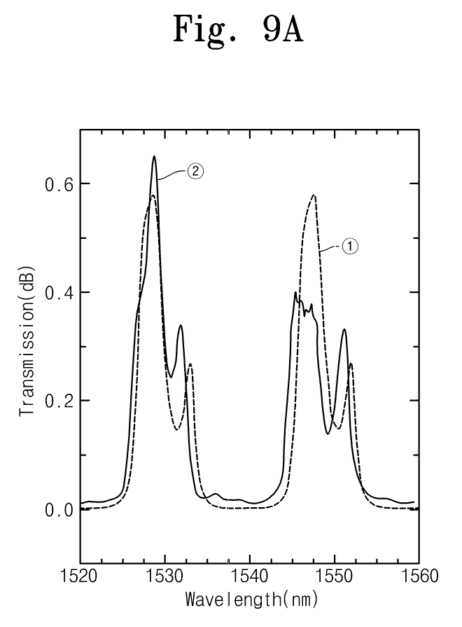

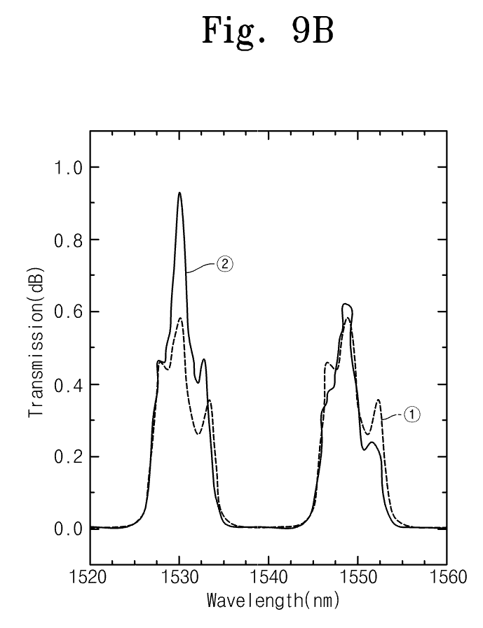

FIGS. 9A to 9C illustrate transmission spectrums of a ring resonator when an embeded layer on a ring disposed at the middle of three rings of the embodiments, which are described with reference to FIGS. 8A and 8B, is selectively etched. The curves \textcircled{1} indicated with the solid line in the spectrums represent theoretically calculated values, and the curves \textcircled{2} indicated with the dotted line represent actual experimental values.

FIG. 9A illustrates transmission spectrums before the embeded layer is etched. FIG. 9B illustrates transmission spectrums when the embeded layer is repeatedly etched three times at an etching speed of about 500 Å/min for about 30 seconds each. FIG. 9C illustrates transmission spectrums when the embeded layer is repeatedly etched five times at an etching speed of about 500 Å/min for about 30 seconds each. An etching amount of the embeded layer according to a time is the same as shown in FIG. 8B.

In FIG. 9A, peaks having a high transmission value at about 1530 nm and about 1550 nm are caused by the rings positioned at the edge among the rings. The peaks having a long wavelength of about 3.2 nm and a low transmission value is caused by the ring positioned at the middle.

Referring to FIG. 9B, it is confirmed that peaks caused by the middle ring are shifted into a low wavelength region. However, it is confirmed that peaks caused by the edge ring ire not shifted.

Referring to FIG. 9C, peaks caused by the middle-positioned ring are shifted to a lower wavelength region. Additionally, peaks caused by the edge rings are not shifted.

Although a photolithography process is performed, the widths of the rings constituting the core and the intervals between the rings may vary. Because of that, the rings may have respectively different resonance wavelengths. As shown in the graphs, resonance wavelengths of each ring can be independently controlled in the ring resonance according to the embodiments of the present invention. Since the resonance wavelength of each ring can be controlled separately, if a form of a transmission spectrum is inappropriate (for example, a form of a transmission spectrum is a spiky type), an appropriate transmission spectrum can be obtained by adjusting the thickness of the embeded layer.

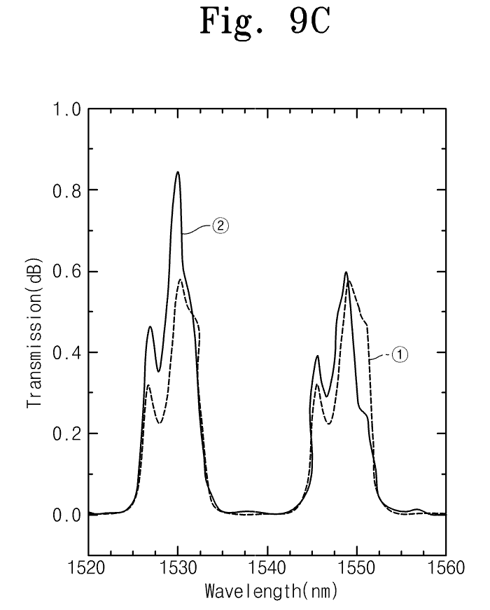

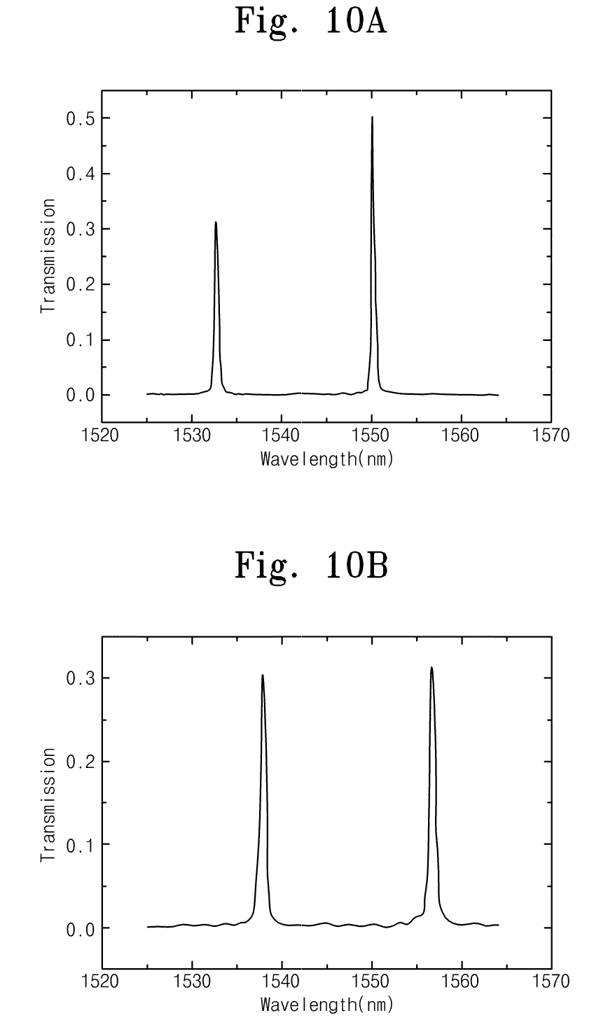

FIGS. 10A and 10B illustrate transmission spectrums about ring resonators where an air cladding layer (when a core is exposed to air) and an embeded layer are separately inserted. FIG. 10A illustrates a transmission spectrum of a ring resonator having an air cladding layer. Rings in the ring resonator are disposed at the minimum interval of about 100 nm. FIG. 10B illustrates a transmission spectrum of a ring resonator having an embeded layer. Rings in the ring resonator are disposed at the minimum interval of about 150 nm.

A quality factor(Q factor), measured about each ring resonator is 3875 in case of a ring resonator including an air cladding layer, and is 2422 in case of a ring resonator including an embeded layer. Through this, in order to realize a ring resonator having a Q factor equivalent to that of the air cladding layer, it can be estimated that the minimum interval between rings should be more than about 160 nm. The rings having an interval of more than about 160 nm can be realized by a photolithography process. Accordingly, a ring resonator that can be formed only by a typical E-beam lithography process can be also realized by a photolithography process.

In a case of the photolithography process, it is advantageous to mass production and has a high affinity to a CMOS process. Therefore, a method of fabricating an optical device according to the embodiments of the present invention is very efficient in fabricating an optical device including a CMOS region.

Additionally, in a case of rings formed by a photolithography process according to the embodiments of the present invention, a statistical error of a resonance wavelength due to a fabricating process is less than when rings are formed by the E-beam photolithography process. Accordingly, it is very efficient to reduce an error of a resonance wavelength of rings.

According to the embodiments of the present invention, a core including a plurality of rings and a ring resonator formed of a cladding layer are provided on a substrate. An embeded layer is interposed between the core and the cladding layer. The embeded layer may reduce an effective coupling distance between the rings. Because of the reduction of an effective coupling distance, the ring resonator may be formed by more accurate and simple fabricating processes. Accordingly, reliability of an optical device including the ring resonator can be improved.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An optical device comprising:
a substrate; and
a ring resonator on the substrate;
wherein the ring resonator comprises:
a cladding layer including a lower cladding layer and an upper cladding layer on the substrate;
a core including a plurality of rings between the lower cladding layer and the upper cladding layer; and
an embeded layer interposed between the core and the cladding layer and having a refractive index less than that of the core and more than that of the cladding layer.

2. The optical device of claim 1, wherein the rings are spaced from each other, and the embeded layer is provided to a space between the spaced rings.

3. The optical device of claim 1, wherein;
the core is formed of silicon;
the cladding layer is formed of a silicon oxide; and
the embeded layer is formed of a silicon nitride or a silicon oxynitride.

4. The optical device of claim 1, wherein an interval between the rings varies.

5. The optical device of claim 4, wherein a thickness of the embeded layer adjacent to at least one ring is different from that of the embeded layer adjacent to another ring.

6. The optical device of claim 4, wherein the interval between the rings is more than or equal to about 160 nm.

7. The optical device of claim 1, wherein the optical device further comprises a complementary metal oxide semiconductor (CMOS) region including a channel layer, the CMOS region being spaced from the ring resonator, the channel layer being provided at the same height as the core and being formed of the same material as the core.

8. A method of fabricating an optical device, the method comprising:
providing a substrate including a resonance region;
forming a plurality of rings through patterning a core layer on the substrate in the resonance region;
forming an embeded layer at a space between the rings of the core; and
forming a cladding layer on the embeded layer,
wherein the embeded layer has a refractive index less than that of the core and more than that of the cladding layer.

9. The method of claim 8, wherein the patterning of the core uses a photolithography process.

10. The method of claim 9, wherein the patterning of the core layer is performed to allow an interval of the rings to be more than or equal to about 160 nm.

11. The method of claim 8, wherein:
the substrate and the core layer are formed of silicon; and
the substrate comprises the core layer and a buried oxide layer interposed between the substrate and the core layer.

12. The method of claim 11, wherein:
the substrate further comprises a CMOS region spaced apart from the resonance region; and the patterning of the core layer comprises forming a channel layer of a transistor in the CMOS region.

13. The method of claim 8, wherein the forming of the embeded layer at the space between the core layer and the rings comprises forming the embeded layer on the rings.

14. The method of claim 13, further comprising adjusting a spectrum of a resonance wavelength by etching an embeded layer on at least one ring to allow a thickness of the embeded layer to be thinner than that of an embeded layer on another ring.

15. The method of claim 8, wherein:
the core layer is formed of silicon;
the cladding layer is formed of a silicon oxide; and
the embeded layer is formed of a silicon nitride or a silicon oxynitride.
